(19) United States
(12) Patent Application Publication
(10) Pub. No.: US 2009/0001415 A1
(43) Pub. Date: Jan. 1, 2009

(54) MULTI-GATE TRANSISTOR WITH STRAINED BODY

(76) Inventors: Nick Lindert, Beaverton, OR (US); Walid Mac Hafez, Portland, OR (US); Jeng-Ya David Yeh, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/772,199

(22) Filed: Jun. 30, 2007

(51) Int. Cl. H01L 29/778; H01L 21/335

(52) U.S. Cl. 257/190; 438/164; 257/E21.403; 257/E29.246

(57) ABSTRACT

A semiconductor device comprises a semiconductor body having a top surface and laterally opposite sidewalls formed on a substrate, wherein the semiconductor body comprises a silicon alloy core having a top surface and laterally opposite sidewalls formed on a silicon fin structure, and a silicon shell layer formed on the top surface and the laterally opposite sidewalls of the silicon alloy core, wherein the silicon alloy core imparts a strain on the silicon shell layer. The semiconductor device further comprises a gate dielectric layer formed on the top surface and the laterally opposite sidewalls of the semiconductor body and a gate electrode formed on the gate dielectric layer.

### BACKGROUND

In the manufacture of integrated circuit devices, nonplanar transistors, such as tri-gate transistors, are often used for fully depleted substrate transistor applications. A conventional tri-gate transistor includes a nonplanar semiconductor body having a top surface and laterally opposite sidewalls. The semiconductor body is formed on a bulk semiconductor substrate or a silicon-on-insulator substrate. A gate dielectric surrounds the semiconductor body and a gate electrode surrounds the gate dielectric. More specifically, the gate dielectric is formed on the top surface and sidewalls of the semiconductor body, while the gate electrode is formed over the gate dielectric on the top surface of the semiconductor body and adjacent to the gate dielectric on the sidewalls of the semiconductor body. The gate dielectric and gate electrode are therefore adjacent to three surfaces of the semiconductor body.

Source and drain regions are formed in the semiconductor body on opposite sides of the gate electrode. Because the gate electrode and the gate dielectric surround the semiconductor body on three sides, the transistor essentially has three separate channels and gates. Because there are three separate channels formed in the semiconductor body, the semiconductor body can be fully depleted when the transistor is turned “ON”, thereby enabling the formation of a fully depleted transistor with gate lengths of less than 30 nanometers.

The semiconductor body is generally formed of silicon. Inducing some form of strain in the silicon enhances channel mobility, which reduces electrical resistance, improves efficiency, increases current, and increases speed. Unfortunately, satisfactory methods have not been developed for straining the silicon used in forming a nonplanar semiconductor body. Therefore, a novel process for straining silicon in nonplanar semiconductor bodies is highly desired.

### BRIEF DESCRIPTION OF THE DRAWINGS

FIG. 1 illustrates a tri-gate transistor having a strained semiconductor body in accordance with an implementation of the invention.

FIG. 2 is a method of forming a tri-gate transistor having a strained semiconductor body in accordance with an implementation of the invention.

FIGS. 3A through 3I illustrate structures formed when carrying out the method of FIG. 2.

### DETAILED DESCRIPTION

Described herein are systems and methods for straining silicon in nonplanar semiconductor bodies. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

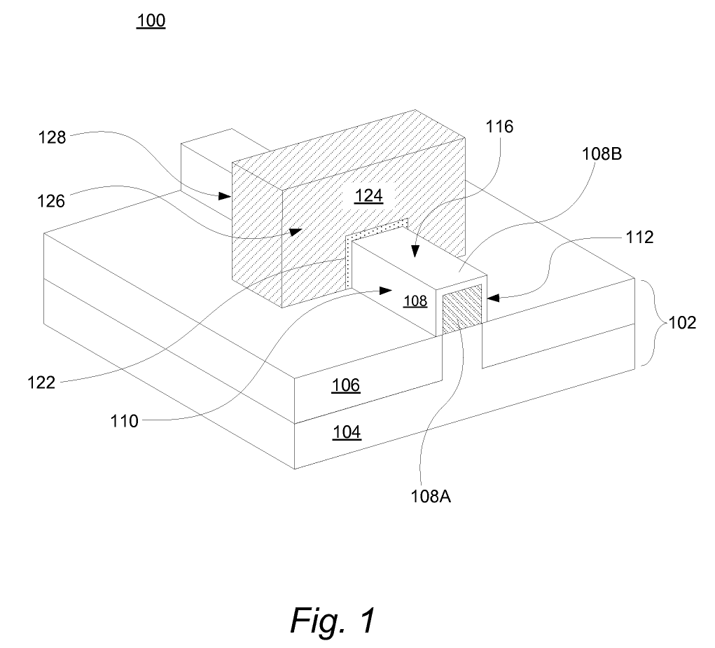

FIG. 1 is a perspective view of a multi-gate transistor 100 having a strained semiconductor body in accordance with an implementation of the invention. The multi-gate transistor 100, here a tri-gate transistor 100, is formed on a substrate 102. The substrate 102 is an insulating substrate which includes a lower monocrystalline silicon substrate 104 upon which is formed an insulating layer 106, such as a silicon dioxide layer. The tri-gate transistor 100, however, can be formed on any well-known insulating substrate such as substrates formed from silicon dioxide, nitrides, oxides, and shappires. In an implementation of the invention, the substrate 102 can be a semiconductor substrate, such as but not limited to monocrystalline silicon substrate and gallium arsenide substrate.

The tri-gate transistor 100 includes a semiconductor body 108 formed on the substrate 102. The semiconductor body 108 has a pair of laterally opposite sidewalls 110 and 112 separated by a distance which defines a semiconductor body width. Additionally, the semiconductor body 108 has a top surface 116. The distance between the top surface 116 and the substrate 102 defines a body height. In an implementation of the invention, the body height is substantially equal to the body width. In an implementation of the invention, the body 108 has a width and height that is less than 30 nanometers (nm) and ideally less than 20 nm.

In accordance with implementations of the invention, the semiconductor body 108 is a dual-material structure having a core 108A formed of a silicon alloy, such as silicon germanium (Si₁₋ₓGeₓ), and a shell layer 108B formed of silicon (Si). In alternate implementations, the shell layer 108B may be formed from alternate semiconductor materials including, but not limited to germanium or gallium, while the silicon alloy core 108A may be formed of an alloy that corresponds to the semiconductor material used in the shell 108B.

In implementations where the silicon alloy core 108A is formed of silicon germanium and the shell layer 108B is formed of silicon, the silicon germanium creates a strain on the silicon shell layer. This strain enhances the mobility of the electrons and holes in the silicon. As discussed below, this mobility may be further enhanced through the addition of stress memorization and/or stress liners.

The strain is caused by a lattice mismatch between the silicon germanium and the silicon. Due to the tetragonal distortion of the silicon germanium material, this lattice mismatch is greatest in a plane perpendicular to the surface of the substrate 102. As such, the strain substantially occurs in the sidewalls of the semiconductor body 108. The strain that is created is tensile in the direction of current flow, thereby enhancing carrier mobility. In a plane parallel to the surface of the substrate 102, the lattice constant of the silicon germanium is substantially matched to the lattice constant of the silicon, therefore there is little or no strain in this plane.

The tri-gate transistor 100 further includes a gate dielectric layer 122 that is formed on and around three sides of semiconductor body 108 as shown in FIG. 1. The gate dielectric layer 122 is formed on or adjacent to the sidewall 11 2, on the top surface 11 6, and on or adjacent to the sidewall 110 of the body 108 as shown in FIG. 1. The gate dielectric layer 122 may be formed using any well-known gate dielectric material, including but not limited to silicon dioxide (SiO₂), silicon oxynitride (SiOₓN_{y}), silicon nitride (Si₃N₄), and high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In an implementation of the invention, the gate dielectric layer 122 may be formed to a thickness of between 5 and 20 Angstroms (Å).

The tri-gate transistor 100 also includes a gate electrode 124. The gate electrode 124 is formed on and around gate dielectric layer 122 as shown in FIG. 1. The gate electrode 124 is formed on or adjacent to the gate dielectric 122 formed on the sidewall 112 of semiconductor body 108, is formed on the gate dielectric 122 formed on the top surface 116 of semiconductor body 108, and is formed adjacent to or on the gate dielectric layer 122 formed on the sidewall 110 of semiconductor body 108. The gate electrode 124 has a pair of laterally opposite sidewalls 126 and 128 separated by a distance which defines the gate length (Lg) of transistor 100. In an implementation of the invention, the laterally opposite sidewalls 126 and 128 of the gate electrode 124 run in a direction perpendicular to the laterally opposite sidewalls 110 and 112 of the semiconductor body 108.

The gate electrode 124 can be formed of any suitable gate electrode material. In an implementation of the invention, the gate electrode 124 may be formed from materials that include, but are not limited to, polysilicon, tungsten, ruthenium, palladium, platinum, cobalt, nickel, hafnium, zirconium, titanium, tantalum, aluminum, titanium carbide, zirconium carbide, tantalum carbide, hafnium carbide, aluminum carbide, other metal carbides, metal nitrides, and metal oxides. In some implementations, the gate electrode 124 may be a composite stack of thin films, such as but not limited to a polysilicon/metal electrode or a metal/polysilicon electrode.

A source region and a drain region (not labeled) are formed in the semiconductor body 108 on opposite sides of the gate electrode 124. The source and drain regions are formed of the same conductivity type such as N-type or P-type conductivity. The source and drain regions may have a uniform doping concentration or may include sub-regions of different concentrations or doping profiles such as tip regions (e.g., source/drain extensions). In some implementations the source and drain regions may have the same doping concentration and profile while in other implementations they vary.

The portion of semiconductor body 108 located between source and drain regions defines a channel region of transistor 100 (not labeled). The channel region may also be defined as the area of the semiconductor body 108 surrounded by the gate electrode 124. In an implementation of the invention, when the channel region is doped it is typically doped to the opposite conductivity type of the source and drain regions. For example, when the source and drain regions are N-type conductivity the channel region would be doped to P-type conductivity. Similarly, when the source and drain regions are P-type conductivity the channel region would be N-type conductivity. The channel region can be uniformly doped or may include “halo” regions. Because the channel region is surrounded on three sides by the gate electrode 124 and the gate dielectric 122, the transistor 100 can be operated in a fully depleted manner. For instance, when the transistor 100 is turned “on” the channel region fully depletes, thereby providing the advantageous electrical characteristics and performance of a fully depleted transistor.

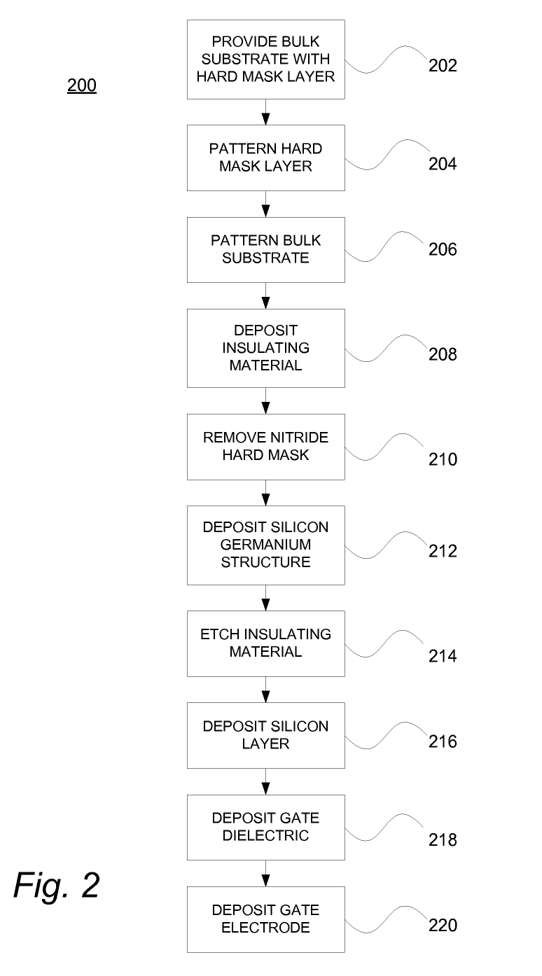

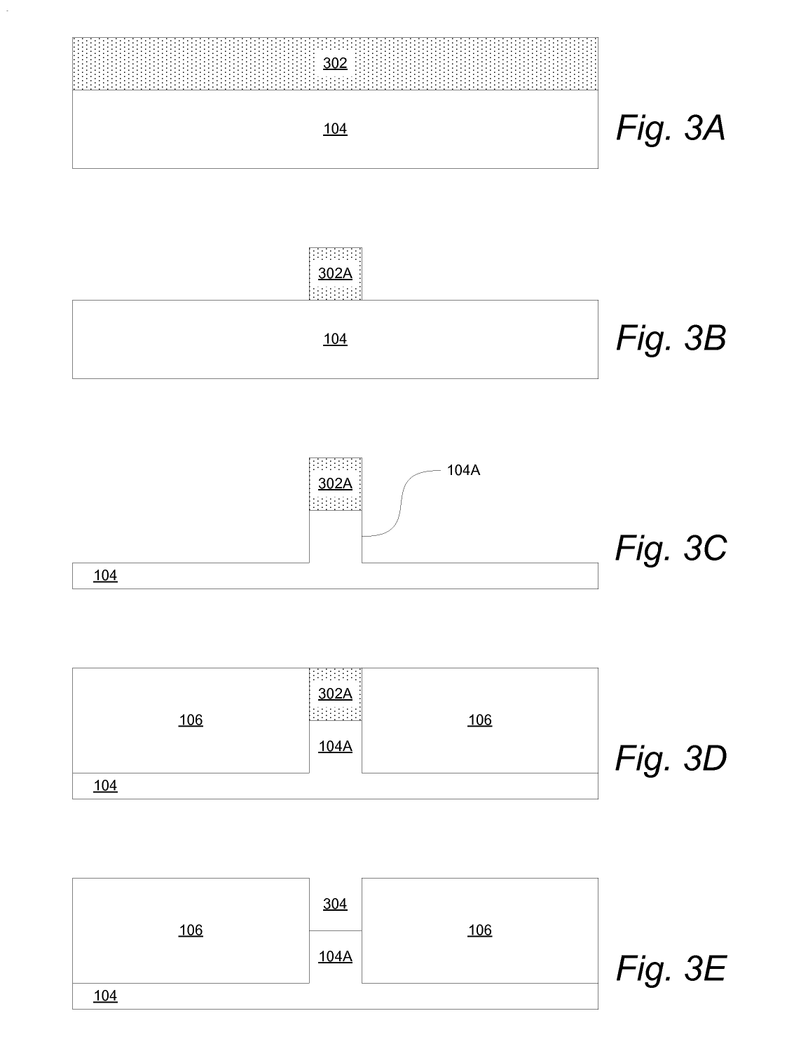

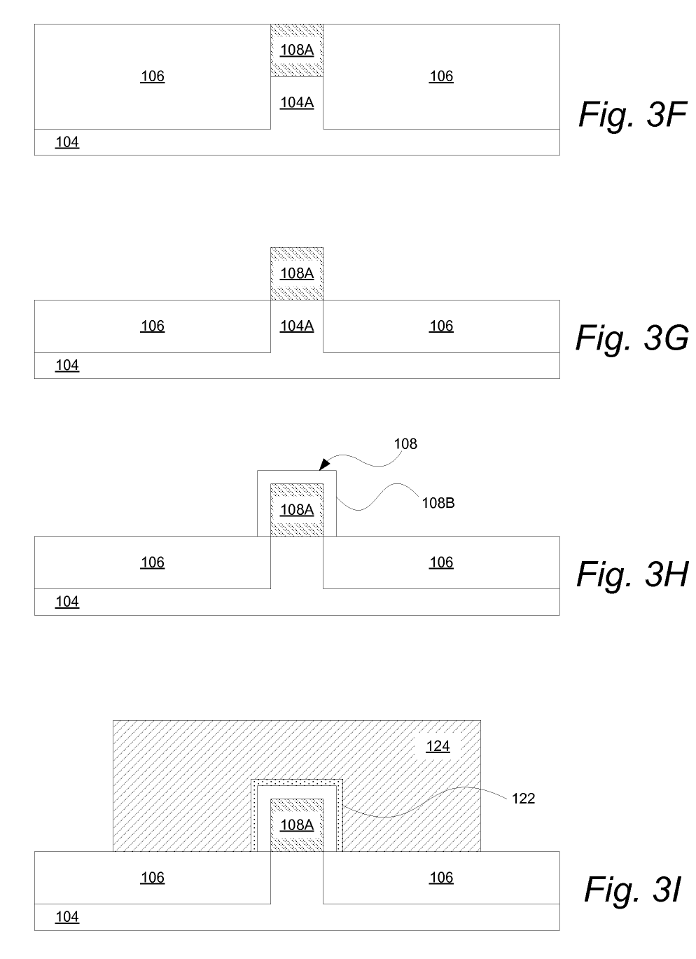

FIG. 2 is a method 200 of forming a multi-gate transistor, in particular a tri-gate transistor, having a novel strained semiconductor body such as the semiconductor body 108 of FIG. 1 in accordance with an implementation of the invention. In further implementations, the multi-gate transistor that is formed with the strained semiconductor body of the invention may be any one of a variety of multi-gate transistors available, such as a double-gate transistor, a tri-gate transistor, a FinFET, or an Omega-FET device. FIGS. 3A to 31 illustrate cross-sections of structures that are formed when the method 200 is carried out.

The method 200 begins by providing a bulk substrate upon which the strained semiconductor body of the invention may be formed (202 of FIG. 2). In the implementation of the invention described here, the bulk substrate may be formed from silicon. In further implementations, the bulk substrate may be formed from materials such as silicon germanium, indium antimonide, lead telluride, indium arsenide, indium phosphide, gallium arsenide, or gallium antimonide, any of which may be combined with silicon. Furthermore, materials previously mentioned above may be used in the bulk substrate.

The silicon bulk substrate includes a hard mask layer formed from a material such as silicon nitride (e.g., Si₃N₄). The silicon nitride hard mask layer may be formed using conventional processes, such as performing a nitridation process on a top surface of the silicon bulk substrate. FIG. 3A illustrates a cross-section of a bulk substrate 104 that includes a silicon nitride layer 302 formed on its top surface.

The hard mask layer may be etched to form a patterned hard mask layer (204). Conventional processes known in the art may be used to pattern the hard mask layer, such as conventional lithography processes. The patterned hard mask layer may then be used as a mask to pattern the bulk substrate and form a silicon fin structure (206). Conventional processes known in the art may be used to pattern the bulk substrate, such as a wet or dry etching process for silicon. FIG. 3B illustrates a cross-section of a patterned hard mask structure 302A on the bulk substrate 104. FIG. 3C illustrates a cross-section of a silicon fin structure 104A that has been formed by etching the bulk substrate 104 using the patterned hard mask structure 302A as a mask.

Next, an insulating material, such as a material used in shallow trench isolation (STI) applications, is deposited around the fin structure (208). In various implementations of the invention, the insulating material may be a dielectric material or another oxide material. In one implementation, silicon dioxide may be used as the insulating material. The insulating material may be deposited using conventional deposition processes, such as epitaxial growth, chemical vapor deposition (CVD), physical vapor deposition (PVD), and atomic layer deposition (ALD). In conventional processes, the insulating material is deposited as a thick layer that even covers the nitride mask structure. This thick insulating layer is then polished back down until the nitride mask structure is exposed. FIG. 3D illustrates a cross-section of an insulating material 106 that has been deposited adjacent to the fin structure 104A.

After the insulating material has been deposited, the nitride hard mask structure is removed (210). Conventional processes may be used to remove the nitride structure, such as known wet or dry etching processes. FIG. 3E illustrates a cross-section of a trench 304 that is formed after the nitride hard mask structure 302A has been removed. In the event an oxide layer forms on a top surface of the fin structure 104A during the removal process for the nitride hard mask structure 302A, the oxide layer may be removed using a wet etch process as is well known in the art.

A deposition process is then carried out to deposit a silicon alloy, here silicon germanium (Si₁₋ₓGeₓ), within the trench on the exposed surface of the fin structure (212). The deposited silicon germanium functions as a core material for the strained semiconductor body being formed by the method 200 of FIG. 2. In some implementations, an epitaxial growth process may be used to selectively grow the silicon germanium on the silicon fin structure. In further implementations, alternate deposition processes may be used. FIG. 3F illustrates a cross-section of a silicon germanium structure 108A that is formed within the trench 304.

When the silicon germanium structure 108A is formed, the lattice constant on the top surface of the silicon germanium structure may expand and the lattice constant on the sidewalls may contract due to the presence of a free surface. In general, the lattice constants (a) after etching will be a_{sidewall}>aₜₒₚ>aₛᵢ. In implementations of the invention, the thickness of this silicon germanium layer may need to be optimized for performance/yield tradeoffs, but should not be so thick as to cause relaxation.

After the silicon germanium is deposited, the insulating material may be recessed to expose the sidewalls of the silicon germanium structure (214). A conventional etching process, such as a wet or dry etch process, may be used to recess the insulating layer. FIG. 3G illustrates the recessed insulating layer 106 and the silicon germanium structure 108A having newly exposed sidewalls.

A silicon shell layer is then selectively deposited over the silicon germanium structure (216). The silicon shell layer encapsulates the silicon germanium structure and, in combination with the silicon germanium structure, forms a strained semiconductor body in accordance with implementations of the invention. An epitaxial deposition process may be used to grow the silicon shell layer on the silicon germanium structure. FIG. 3H illustrates a silicon shell layer 108B formed on the top and sidewalls of the silicon germanium structure 108A. The silicon shell layer 108B and the silicon germanium structure 108A combine to form a strained semiconductor body 108.

As described above, the lattice constant of the silicon germanium in a plane perpendicular to the substrate surface is larger than the lattice constant of silicon due to the tetragonal distortion of the silicon germanium material, while the lattice constant of the silicon germanium in a plane parallel to the substrate surface is substantially the same as that of silicon. The silicon germanium therefore imposes its lengthened vertical cell dimension on the already smaller cell dimension of the silicon shell layer, imparting a strain on the deposited silicon shell layer. The strain is greatest on the silicon that is formed on the sidewalls of the silicon germanium structure (i.e., the silicon formed in a plane perpendicular to the substrate surface). The silicon shell layer will therefore witness substantial tensile strain adjacent to the sidewalls of the silicon germanium structure and a lower tensile strain adjacent to the top of the silicon germanium structure.

Once the strained semiconductor body is formed, the remainder of the process to form a tri-gate device may follow a conventional process flow. For instance, conventional deposition and etching processes may be used to deposit a gate dielectric layer (218) and a gate electrode (220). Materials that may be used in the gate dielectric layer and the gate electrode were described above. FIG. 31 illustrates a cross-section of a gate dielectric layer 122 and a gate electrode 124 that have been formed over the strained semiconductor body 108 of the invention.

In further implementations of the invention, a conventional stress memorization technique and/or a conventional stress liner may be used in conjunction with the strained semiconductor body described herein. While the silicon germanium core material of the strained semiconductor body creates a strain on the inner surface of the silicon shell layer (i.e., the silicon shell surface that is in contact with the silicon germanium core), a stress memorization technique and/or a stress liner may create a second additional strain on the exposed outer surface of the silicon shell layer. These techniques add to the already tensile-strained channel to provide further electron mobility gain. In some implementations, the stress memorization technique may include polyamorphization with a stress liner deposition and an annealing process. For instance, the addition of a stress liner followed by an anneal causes recrystallization of the gate electrode material with compressive strain that transfers tensile strain to each of the tri-gate channels. In some implementations, the lattice structure of an added stress liner may be different than the lattice structure of the silicon shell layer, thereby imparting a strain on the silicon shell layer in a manner that is similar to the silicon germanium. Since stress memorization techniques and stress liners are well known in the art, they will not be discussed in greater detail.

In yet further implementations of the invention, the top surface of the silicon shell layer may be formed separately from the sidewall surfaces of the silicon shell layer. For instance, after the silicon germanium is grown in the trench, a silicon layer may be formed on the top surface of the silicon germanium prior to recessing the insulating layer. After the top surface silicon layer is formed, the insulating layer may be recessed and silicon may be formed on the sidewalls of the silicon germanium structure. In this manner, the top surface of the silicon shell layer may be tailored independently of the sidewall surfaces of the silicon shell layer.

Accordingly, a novel, strained semiconductor body has been described for use in multi-gate devices. The strained semiconductor body of the invention includes a silicon germanium core material and a silicon shell layer, wherein the silicon germanium imparts a strain on the silicon shell layer. The creation of a strain in the silicon shell layer enables an improvement in carrier mobility, leading to an improved transistor. Furthermore, the increased gate width due to the silicon shell layer growth increases the active area without needing to shrink the trench width or depth.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

1. A semiconductor device comprising:
a semiconductor body having a top surface and laterally opposite sidewalls formed on a substrate, wherein the semiconductor body comprises:
a silicon alloy core having a top surface and laterally opposite sidewalls formed on a silicon fin structure, and
a silicon shell layer formed on the top surface and the laterally opposite sidewalls of the silicon alloy core, wherein the silicon alloy core imparts a strain on the silicon shell layer;
a gate dielectric layer formed on the top surface and the laterally opposite sidewalls of the semiconductor body; and
a gate electrode formed on the gate dielectric layer.

2. The semiconductor device of claim 1, wherein the silicon alloy comprises silicon germanium.

3. The semiconductor device of claim 1, further comprising a source region and a drain region formed in the semiconductor body on opposite sides of the gate electrode.

4. The semiconductor device of claim 1, further comprising a stress liner formed over the semiconductor body.

5. The semiconductor device of claim 1, wherein the gate dielectric layer comprises a material selected from the group consisting of silicon dioxide, silicon oxynitride, silicon nitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

6. The semiconductor device of claim 1, wherein the gate electrode comprises a material selected from the group consisting of polysilicon, tungsten, ruthenium, palladium, platinum, cobalt, nickel, hafnium, zirconium, titanium, tantalum, aluminum, titanium carbide, zirconium carbide, tantalum carbide, hafnium carbide, and aluminum carbide.

7. The semiconductor device of claim 1, wherein the substrate comprises a silicon bulk substrate and an insulating layer.

8. The semiconductor device of claim 1, wherein the silicon alloy core imparts a strain on the silicon shell layer.

9. A method of forming a strained semiconductor body comprising:
forming a hard mask structure on a silicon substrate;
etching the silicon substrate using the hard mask structure to form a silicon fin structure;
depositing an insulating material adjacent to the silicon fin structure and adjacent to the hard mask structure;
removing the hard mask structure after the insulating material is deposited to form a trench in the insulating material above the silicon fin structure;
depositing a silicon alloy material in the trench above the silicon fin structure to form a silicon alloy core having a top surface and laterally opposite sidewalls;
recessing the insulating material to expose the laterally opposite sidewalls of the silicon alloy core; and
depositing a silicon shell layer on the top surface and the laterally opposite sidewalls of the silicon alloy core.

10. The method of claim 9, wherein the silicon alloy material comprises silicon germanium.

11. The method of claim 1 0, wherein the depositing of the silicon alloy material comprises epitaxially growing silicon germanium on the silicon fin structure.

12. The method of claim 9, wherein the depositing of the silicon shell layer comprises epitaxially growing silicon on the silicon alloy core.

13. The method of claim 9, further comprising removing an oxide layer before the depositing of the silicon alloy material.

14. The method of claim 9, wherein the recessing of the insulating material comprises wet etching the insulating material until the laterally opposite sidewalls of the silicon alloy core are at least substantially exposed.

15. The method of claim 9, further comprising depositing a stress liner on the silicon shell layer.
